(19) United States
(12) Patent Application Publication
(10) Pub. No.: US 2009/0184727 A1
(43) Pub. Date: Jul. 23, 2009

(54) Space Transformer, Manufacturing Method of the Space Transformer and Probe Card Having the Space Transformer

(75) Inventors: Ki-Joon Kim, Seoul (KR); Yong-Hwi Jo, Gyeonggi-do (KR); Dong Yeul Choi, Seoul (KR)

Correspondence Address: HARNESS, DICKEY & PIERCE, P.L.C., P.O. BOX 8910, RESTON, VA, 20195, US

(73) Assignee: PHICOM CORPORATION, SEOUL (KR)

(21) Appl. No.: 12/223,967

(22) PCT Filed: Feb. 13, 2007
(86) PCT No.: PCT/KR2007/000759

§ 371 Date: Aug. 14, 2008

(30) Foreign Application Priority Data
Feb. 12, 2006 (KR) 10-2006-0015100

(51) Int. Cl. G01R 31/02; H05K 3/10

(52) U.S. Cl. 324/754; 29/846

(57) ABSTRACT

Provided is a probe card of a semiconductor testing apparatus, including a printed circuit board to which an electrical signal is applied from external, a space transformer having a plurality of probes directly contacting with a test object, and interconnectors connecting the printed circuit board to the probes of the space transformer. The space transformer includes substrate pieces which the probes are installed on one sides of, and a combination member joining and unifying the substrate pieces together so as to form a large-area substrate with the substrate pieces on the same plane. This probe card is advantageous to improving flatness even with a large area, as well as testing semiconductor chips formed on a wafer in a lump.

### TECHNICAL FIELD

The present invention relates to apparatuses for testing semiconductor devices. In particular, the present invention relates to a large-area space transformer, a method of fabricating the space transformer capable of simultaneously testing semiconductor chips on a large-scaled wafer, and a probe card having the space transformer.

### BACKGROUND ART

Semiconductor devices are typically manufactured in the pattern of chips divisionally formed on a substrate like a semiconductor wafer by repeating various unit processing steps such as oxidation, diffusion, etching, and metallization. During this, chip failures could be usually caused by defects arising from the processing steps of the semiconductor devices. Thus, it is preferred to detect chip failures before conducting a sawing step of the substrate for a package process, which is advantageous to improving a yield of the semiconductor devices and reducing a product cost thereof.

In detecting fails of chips formed on a substrate, a probing system is used to conduct an electrical die sorting (EDS) process for testing electrical characteristics of the chip. The EDS process is carried out with determining a chip failure from comparing data, which are preliminarily stored in a test system, to electrical characteristics obtained by applying currents directly to contact pads provided to a chip on a substrate.

In the meantime, with advancement of semiconductor technology, the more number of chips are increasingly fabricated on a single substrate or wafer in purpose of reducing a product cost and raising the productivity. In recent, a 300 mm-wafer process has been adopted to accelerate an increase of the number of semiconductor chips (e.g., 64 DUT or 128 DUT).

Nevertheless of that, the current technology for testing semiconductor chips is still insufficient to correspond with such variation of wafer dimensions. Especially, a typical one to be required nowadays in technology for testing semiconductor chips is relevant to the development of large-area probe cards.

### DISCLOSURE OF INVENTION

### Technical Problem

In recent, space transformers are fabricated by way of micro-electromechanical systems (MEMS) and semiconductor technology in semiconductor processing lines with 4˜6 inches. From the reason, it is difficult to fabricate a space transformer of a large-area probe card, which is capable of testing 64 or 124 chips on a 300 mm-substrate in a lump, because of technology limit. And, in fabricating a space transformer suitable for a large-area probe card, it needs to change conventional equipment with an expensive one (capable of conducting a process with 8 or 12 inches), so takes a great time and cost for replacing the equipment thereof.

Further, as a probe card becomes larger in area, it is more necessary to fabricate a large-area space transformer in correspondence with a larger area of the probe card. But, such a large-area space transformer is much less than a conventional small-area space transformer in flatness, so degrades the resultant yield on fabrication.

In addition, if there is even generated at least one defect of probe on the space transformer, it is regarded as being a defect over the entire probe fabrication as a whole. Thus, since a large-area space transformer has many probes relative to a small-area space transformer, it is probably high in generating a defect of probe rather than the small-area space transformer.

### Technical Solution

The present invention provides a large-area space transformer capable of testing entire chips on a wafer in a lump, a method of fabricating the space transformer, and a probe card having the space transformer.

The present invention also provides a large-area space transformer capable of enhancing test efficiency and reducing a cost for test, a method of fabricating the space transformer, and a probe card having the space transformer.

The present invention provides a large-area space transformer capable of enhancing flatness and yield, a method of fabricating the space transformer, and a probe card having the space transformer.

The present invention provides a large-area space transformer with various dimensions, a method of fabricating the space transformer, and a probe card having the space transformer.

The present invention provides a large-area space transformer suitable for making a large-area probe card by means of spacer transformers fabricated through a semi-conductor processing line (smaller than 6 inches), a method of fabricating the space transformer, and a probe card having the space transformer.

A probe card of a semiconductor testing apparatus, including: a printed circuit board to which an electrical signal is applied from external; a space transformer having a plurality of probes directly contacting with a test object; and interconnectors connecting the printed circuit board to the probes of the space transformer. The space transformer includes: substrate piece which the probes are installed on one sides of; and a combination member joining and unifying the substrate pieces together so as to form a large-area substrate with the substrate pieces on the same plane.

According to an embodiment of the present invention, the combination member includes at least a frame supporting the substrate pieces, and an adhesive layer joining the frame with the substrate pieces.

According to an embodiment of the present invention, the frame includes a first frame supporting connection parts of the substrate pieces, and a second frame supporting edges of the substrate pieces on other sides. According to an embodiment of the present invention, the first and second frames are joined to each other by an adhesive or linking means.

According to an embodiment of the present invention, each substrate piece of the space transformer comprises a first terminal to which an electrical signal is applied from the interconnector, a second terminal contacting with the probe, and an channel including internal interconnection wire which connects the first terminal with the second terminal.

The present invention also provides a space transformer of a probe card, comprising: substrate pieces each having a plurality of probes contacting directly with a test object; and a combination member joining and unifying the substrate pieces together so as to form a large-area substrate with the substrate pieces on the same plane.

In another aspect of the present invention, a method of fabricating a space transformer of a probe card is comprised of: preparing substrate pieces which a plurality of probes contacting directly with a test object are installed on one sides of; aligning the substrate pieces with each other so as to make a large-area substrate; and fixing the other sides of the aligned substrate pieces to a first frame.

According to an embodiment of the present invention, the method further comprises fixing the one side edges of the substrate pieces, which is fixed to the first frame, to a second frame.

According to an embodiment of the present invention, fixing the substrate pieces to the first frame is carried out with injecting an adhesive into spaces between each of substrate pieces and the first frame and between the substrate pieces.

According to an embodiment of the present invention, aligning the substrate pieces is carried out by aligning, with reference to one of the substrate pieces, the rest of the substrate pieces.

### Advantageous Effects

The present invention offers an art capable of fabricating a large-area space transformer without further investment for additional equipment or system. And, it is able to test all chips of a wafer in a lump, enhancing test efficiency. Further, as the present invention provides a large-area space transformer with good flatness, it is possible to improve a yield with high reliability to electrical interconnection between a probe and a test object (or chip pad). According to the present invention, it is possible to fabricate a space transformer of 12 inches or more than in size.

### BRIEF DESCRIPTION OF THE DRAWINGS

FIG. 1 is a structural view schematically illustrating a probe card in accordance with an embodiment of the present invention.

FIG. 2 is a disassembled perspective of a space transformer in accordance with a preferred embodiment of the present invention.

FIG. 3 is a plane view of the space transformer in accordance with a preferred embodiment of the present invention.

FIG. 4 is a bottom view of the space transformer in accordance with a preferred embodiment of the present invention.

FIG. 5 is a sectional view of the space transformer, taken along the line a-a′ shown in FIG. 3.

FIGS. 6 and 7 are perspective and plane views of an alignment system for arranging four substrate pieces.

FIGS. 8 through 11 are views concretely illustrating a procedure of aligning the four substrate pieces in the alignment system.

### BEST MODE FOR CARRYING OUT THE INVENTION

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art.

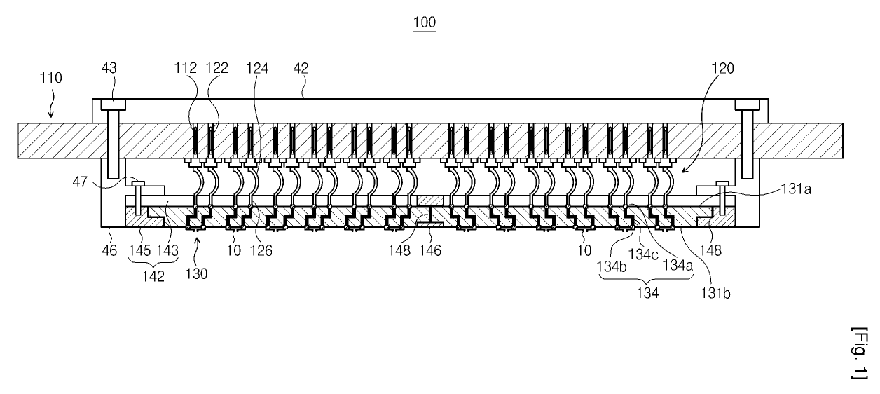

Hereinafter, it will be described about an exemplary embodiment of the present invention in conjunction with FIGS. 1 through 11. Like reference numerals refer to like elements throughout the accompanying figures.

The present invention is basically directed to provide a large-area space transformer, a method of fabricating the space transformer, and a large-area probe card having the large-area space transformer, without further cost for equipment thereof. The present invention is figured in a single large-area space transformer by combining a plurality of small substrates (substrate pieces forming probes on a multi-level circuit board) manufactured through a conventional probe-card mass-production equipment.

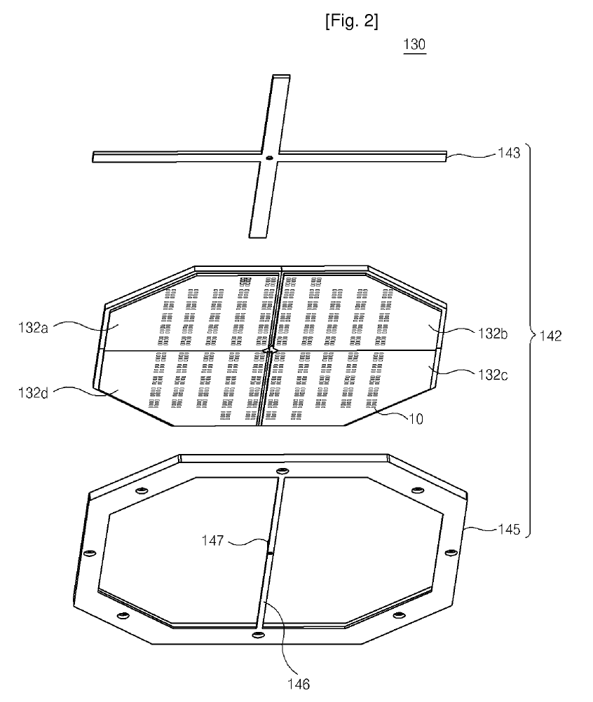

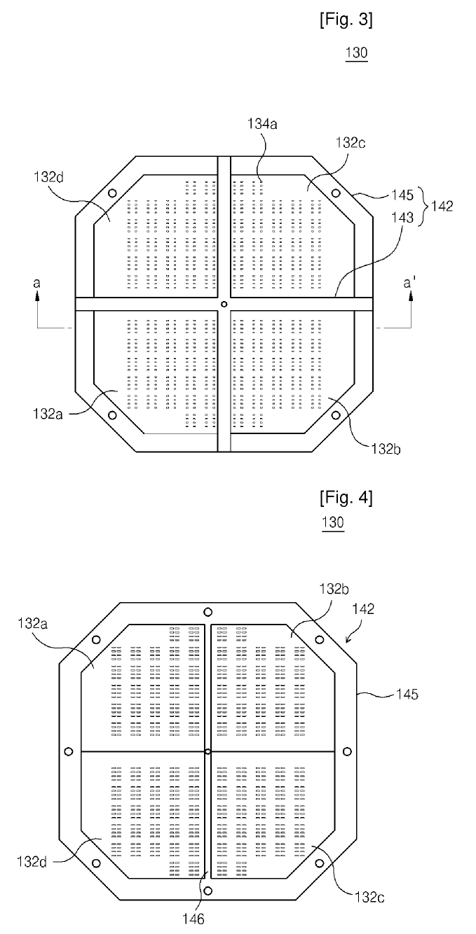

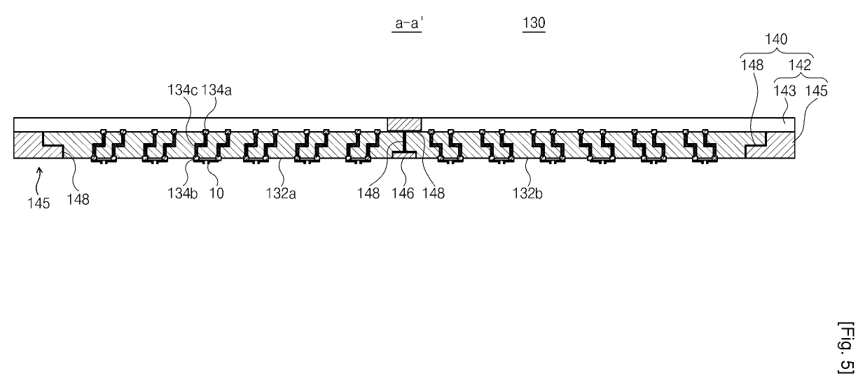

FIG. 1 is a structural view schematically illustrating a probe card in accordance with an embodiment of the present invention. FIGS. 2 through 4 are a disassembled perspective, a plane view, and a bottom view, respectively, of a space transformer in accordance with a preferred embodiment of the present invention. FIG. 5 is a sectional view of the space transformer, taken along the line a-a′ shown in FIG. 3.

Referring to FIGS. 1 and 2, the probe card 100 is used with being installed in a tester (not shown) of a probing system for testing a chip failure through electrical characteristics of chips formed on a semiconductor substrate or wafer (not shown).

The probe card 100 is comprised of a printed circuit board (PCB) 110 on which a plurality of connection holes 112 is formed, a space transformer 130 which a plurality of probes 10, which is directly contacted with a test object (a wafer chip), are attached to the lower surface of, interconnectors 120 as interface means for electrically connecting the PCB 110 and the space transformer 130, and a supporting unit for combinably supporting the space transformer 130 on the PCB 110. The supporting unit is constructed of assistant components such as reinforcement plates 42 and 46 placed on the PCB 110 and the top and bottom of the space transformer 130, and bolts 43 and 47. Linking the assistant components with each other, the space transformer 130 is combinably supported on the PCB 110.

On a surface of the PCB 110, substrate terminals (not shown) formed of plural dots or pads are provided to several positions horizontally and vertically. A connection hole 112 has a conductive film (not shown), which is made of a conductive material such a copper on the inner wall, for connection with an internal circuit.

A second connection 122 of the interconnector 120 is inserted into the connection hole 112. Here, the second connection of the interconnector 120 is shaped in an O-ring type that is hollow and longish. After shrinking by forcible insertion into the connection hole 112, the second connection 122 extends by its own elastic force to make projections thereof contact with the conductive film on the inner wall of the connection hole 112. And, a link 124 of the interconnector 120 is located in a space between the PCB 110 and the space transformer 130 and a first connection 126 thereof contacts with a first terminal 134a of a main channel 134 of the space transformer 130. The interconnector 120, as the interface means electrically connecting the PCB 110 and the space transformer 130, may be shaped in various patterns. For instance, the interconnector 120 may be provided in the pattern of a connection pad contacting with the first terminal of the space transformer at the bottom of the PCB 110. The probe 10, the space transformer 130 having main channels 134, the interconnectors 120, and the PCB 110 are electrically coupled with each other.

Referring to FIGS. 1 through 5, the space transformer 130 is comprised of four substrate pieces 132a, 132b, 132c, and 132d, which probes are respectively installed on the lower surface of, and a combination member 140 linking altogether and unifying the four substrate pieces 132a˜132d so as to form a large-area substrate on the same plane. In this embodiment of the present invention, since each substrate piece has 32 DUT (device under test), it is possible to conduct a probe test for totally 128 chips in a lump.

Each of substrate pieces 132a, 132b, 132c, and 132d includes the probe 10 contacting with chip contact pads (not shown) arranged on a semiconductor substrate to be tested, and channels 134 electrically connecting the probe 10 with the interconnector 120. Each channel is comprised of first terminals 134a contacting with the first connection 126 on a first surface 131a of the space transformer 130, second terminals 134b electrically connected to the probe 10 on a second surface 131b of the space transformer 130, and internal interconnection wires 134c electrically connecting the first terminals 134a with the second terminals 134b, respectively. The substrate pieces 132a˜132d with such structures are manufactured by means of MEMS and semiconductor technology in a processing line for 4˜6-inch wafer.

The combination member 140 includes a frame 142 and an adhesive layer 148. In purpose of supporting the four substrate pieces 132a˜132d arranged on the same plane, the frame 142 is comprised of a first frame 143 supporting connection parts of the substrate pieces on the first surface 131a, and a second frame 145 supporting edges (lower and outer sides) of the substrate pieces 132a˜132d. The first frame 143 is shaped in a pattern of cross to correspond with the connection parts. The second frame 145 is shaped in a pattern of octagonal ring to correspond with the edges of the substrate pieces 132a˜132d arranged therein. The second frame 145 includes a support 146 intersecting the center thereof, and a projection 147 protruded from the support 146 and inserted into a hole formed at the center of the first frame 143. The first and second frames 143 and 145 are combined with each other through combination means such as bolts, or joined together by an adhesive such an epoxy resin. The first and second frames 143 and 145 may be provided in various shapes in accordance with the number and combination pattern of the substrate pieces 132a˜132d.

An adhesive layer 148 is made of an epoxy resin, joining the frame 142 with the substrate pieces 132a˜132d. The epoxy resin is injected into spaces between the first and second frames, 143 and 145, and the substrate pieces 132a˜132d, joining them to each other.

The large-area space transformer 130 aforementioned is fabricated through a procedure as follows.

First, the four substrate pieces 132a˜132d are manufactured in a 4 or 6-inch processing line by means of MEMS and semiconductor technology. This procedure may include a process for cutting the edges of the substrate pieces 132a˜132d into predetermined dimensions and shapes so as to make them arranged to form a large-area substrate with a desired size. These four substrate pieces 132a˜132d are put into a process of alignment to form a predetermined large-area substrate by an alignment system 200 shown in FIG. 6. After aligning the four substrate pieces 132a˜132d, those pieces are fixed to the first frame 142 by an adhesive so as to maintain the state of alignment.

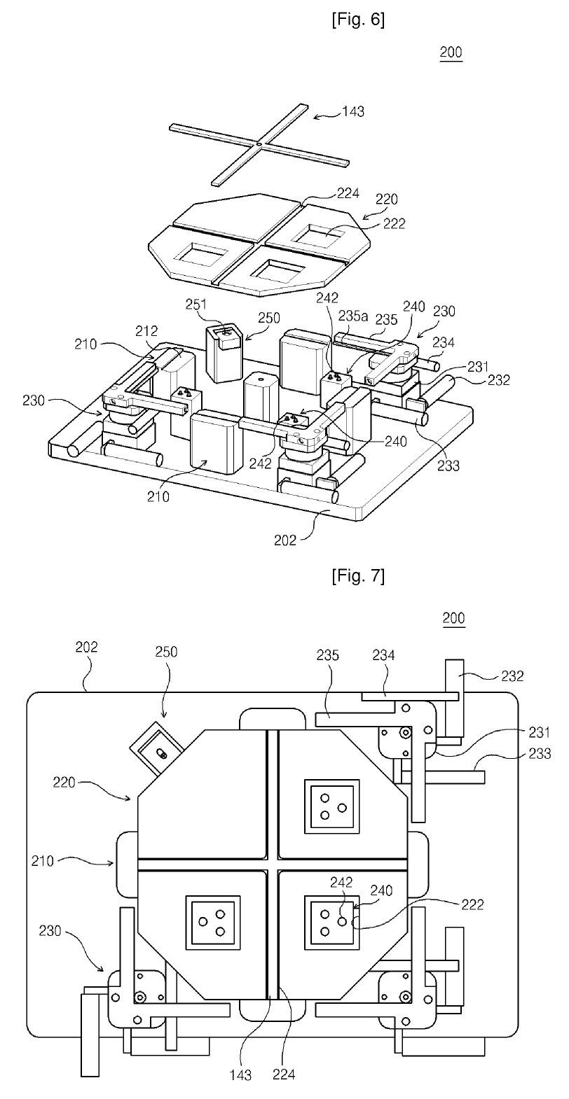

FIGS. 6 and 7 are perspective and plane views of an alignment system for arranging the four substrate pieces.

Referring to FIGS. 6 and 7, the alignment system 200 is comprised of four mounts 210 placed on a base 202, a fixing plate 220 placed on the mounts 210, alignment members 230 operating to align the substrate pieces 132a˜132d with each other, three leveling members 240 equipped with lift pins 242 for adjusting heights of the three substrate pieces 132b˜132d but the substrate piece 132a, and a press-in member 250 for settling the fixing plate 220 thereon.

The press-in member 250 moves forward or backward along a long hole 251, and pushes the fixing plate 220 toward the alignment members 230 to closely fix it on safe zones 212 of the mounts 210.

The mounts 210 are disposed in four directions, having the stepped safe zones 212 on which the fixing plate 220 is laid. The fixing plate 220 includes three openings 222 correspondent with the three leveling members 240. A groove 224 is formed on the upper face of the fixing plate 220, in which the first frame 143 is placed.

The alignment member 230 is comprised of a pillarlike body 231 near to the edge of the base 202, a fixing bar 235 placed on the body 231, and X, Y, and θ axes drivers 232, 233, and 234 installed at the body 231. The fixing bar 235 moves along the X and Y-axes, and horizontally rotates on the θ axis, under control of the drivers 232, 233, and 234. The fixing bar 235 is shaped in a pattern of ‘L’. At a side of the fixing bar 235, i.e., at a side facing the substrate piece, a plurality of vacuum holes 235a are formed lengthwise to fix the outer sides of the substrate piece, which is to be aligned, by vacuum. Meanwhile, the leveling member 240 is provided to set a height level with the substrate piece 132a that acts as a reference for leveling, including the lift pins supporting the bottoms of the substrate pieces 132b˜132d mounted on the fixing plate 220.

Now, hereinafter will be described a procedure of aligning the four substrate pieces in the alignment system structured as aforementioned.

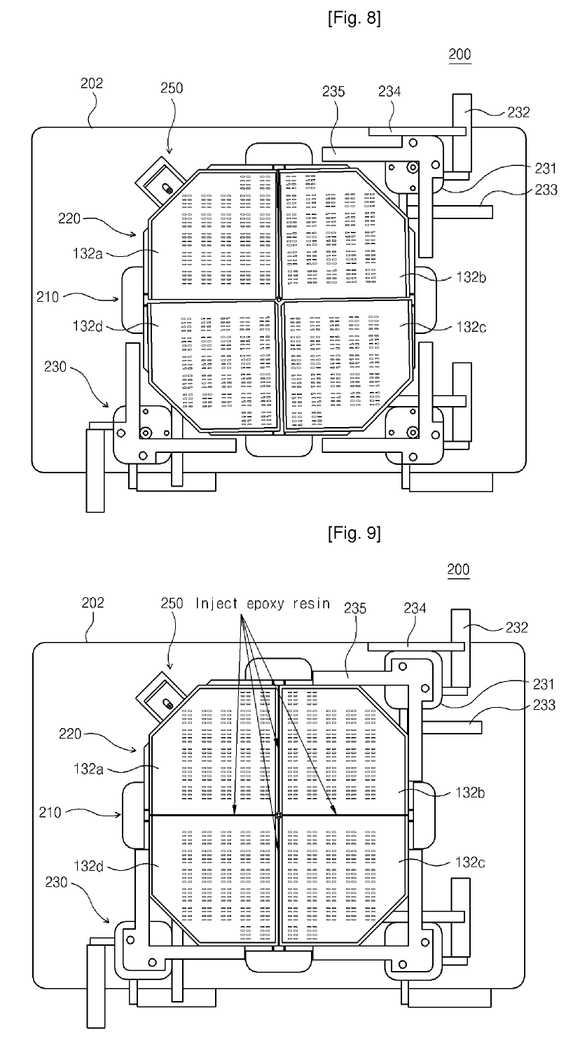

Referring to FIGS. 8 through 11, the four substrate pieces 132a˜132d are laid on the fixing plate 220 settled on the safe zone 212 of the mount 210 (see FIG. 8). Then, in the condition of fixing the substrate piece 132a thereto at the reference position, the rest three substrate pieces 132b˜132d are aligned to the reference position by the substrate piece 132a (see FIG. 9).

This alignment is accomplished by moving the substrate pieces toward a correct coordinate (or position) with checking up an alignment state of the three substrate pieces 132b˜132d by means of a microscope which is normally used for calibrating a coordinate. During this, the alignment and leveling members, 230 and 240, are used for alignment. On the reference level of the substrate piece 132a, the rest substrate pieces 132b˜132d are aligned through fine adjustment by the X, Y, and θ axes drivers 232˜234 and the leveling members 240 in cooperatively adjacent coordinates. Here, the transfer of the substrate pieces 132b˜132d in the alignment system 230 is carried out with being absorbed by vacuum actuated by the vacuum holes 235a of the fixing bars 235.

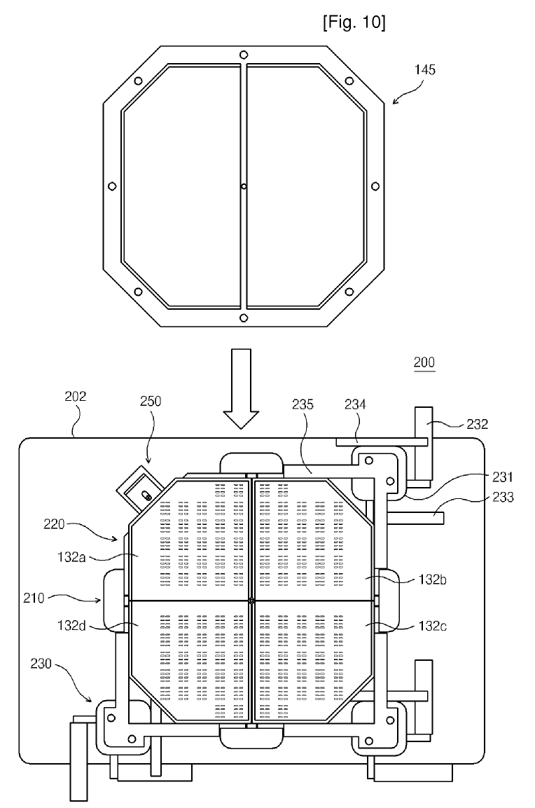

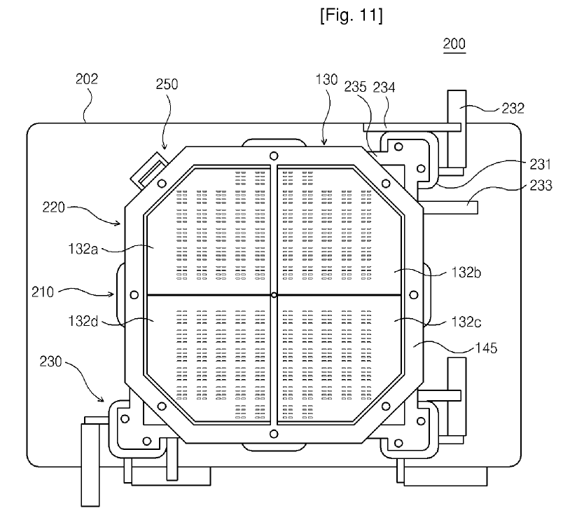

The four substrate pieces 132a˜132d aligned as aforementioned are fixed on the first frame 143 by means of an epoxy resin. Namely, the epoxy resin is injected into spaces between the substrate pieces 132a˜132d for confirming the alignment status of them. The epoxy resin flows into the spaces between the substrate pieces 132a˜132d and between the substrate pieces 132a˜132d and the first frame 143. Then, the epoxy resin hardens to be the adhesive layer 148 for attaching the substrate pieces 132a˜132d to the first frame 143 (see FIG. 10). Next, the second frame 145 is placed to locate at the edges of the four substrate pieces 132a˜132d and an epoxy resin is injected into spaces between the second frame 145 and the substrate pieces 132a˜132d. Thus, the second frame 145 and the substrate pieces 132a˜132d are fixedly adhered to each other (see FIG. 11).

Through this procedure, the four substrate pieces 132a˜132d are joined together to form the large-area space transformer 130.

As aforementioned, since the substrate pieces 132a˜132d are manufactured in small size, it offers good flatness. Therefore, although the substrate pieces 132a˜132d are unified to form a large area, its good flatness contributes to improving reliability of electrical connection between the probe and chips as test objects.

The present invention is available for various modifications or alterations of the large-area space transformer, the method of fabricating the space transformer, and the probe card including the space transformer. The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

### INDUSTRIAL APPLICABILITY

The present invention is concerned with apparatuses for testing semiconductor devices, involved in a large-area space transformer, a method of fabricating the space transformer capable of simultaneously testing semiconductor chips on a large-scaled wafer, and a probe card having the space transformer.

1. A probe card of a semiconductor testing apparatus, comprising: a printed circuit board to which an electrical signal is applied from external; a space transformer having a plurality of probes directly contacting with a test object; and interconnectors connecting the printed circuit board to the probes of the space transformer, wherein the space transformer comprises: substrate pieces which the probes are installed on one sides of; and a combination member joining and unifying the substrate pieces together so as to form a large-area substrate with the substrate pieces on the same plane.

2. The probe card according to claim 1, wherein the combination member comprises: at least a frame supporting the substrate pieces; and an adhesive layer joining the frame with the substrate pieces.

3. The probe card according to claim 2, wherein the frame comprises a first frame supporting connection parts of the substrate pieces.

4. The probe card according to claim 2, wherein the frame comprises: a first frame supporting connection parts of the substrate pieces; and a second frame supporting edges of the substrate pieces.

5. The probe card according to claim 4, wherein the first and second frames are joined to each other by an adhesive or linking means.

6. The probe card according to claim 1, wherein each substrate piece of the space transformer comprises: a first terminal to which an electrical signal is applied from the interconnector; a second terminal contacting with the probe; and an channel including internal connection wire which connects the first terminal with the second terminal.

7. A space transformer of a probe card, comprising: a substrate pieces each having a plurality of probes directly contacting with a test object; and a combination member joining and unifying the substrate pieces together so as to form a large-area substrate with the substrate pieces on the same plane.

8. The space transformer according to claim 7, wherein the combination member comprises: at least a frame supporting the substrate pieces; and an adhesive layer joining the frame with the substrate pieces.

9. The space transformer according to claim 8, wherein the frame comprises: a first frame supporting connection parts of the substrate pieces on one side; and a second frame supporting edges of the substrate pieces on the other side.

10. A method of fabricating a space transformer of a probe card, comprising: preparing substrate pieces which a plurality of probes directly contacting with a test object are installed on one sides of; aligning the substrate pieces with each other so as to make a large-area substrate and fixing the other sides of the aligned substrate pieces to a first frame.

11. The method according to claim 10, wherein the method further comprises: fixing the the one side edges of the substrate pieces, which is fixed to the first frame, to a second frame.

12. The method according to claim 10, wherein fixing the substrate pieces to the first frame is carried out with injecting an adhesive into spaces between each of substrate pieces and the first frame and between the substrate pieces.

13. The method according to claim 10, wherein aligning the substrate pieces is carried out by aligning, with reference to one of the substrate pieces, the rest of the substrate pieces.
